(19) United States
(12) Patent Application Publication
(10) Pub. No.: US 2024/0371807 A1
(43) Pub. Date: Nov. 7, 2024

(54) REDUCED-SIZE DIE, RELATED DEVICES AND METHODS

(71) Applicant: SKYWORKS SOLUTIONS, INC., Irvine, CA (US)

(72) Inventors: Junhyung LEE, Irvine, CA (US); Sundeep Nand NANGALIA, Raleigh, NC (US); Rudolph BORJA, Montebello, CA (US)

(21) Appl. No.: 18/655,269

(22) Filed: May 5, 2024

Related U.S. Application Data
(60) Provisional application No. 63/464,575, filed on May 7, 2023.

(51) Int. Cl. H01L 23/00; H01L 23/528; H01L 23/66; H01L 25/10

(52) U.S. Cl. CPC H01L 24/05; H01L 23/5283; H01L 23/66; H01L 24/03; H01L 24/16; H01L 25/105; H01L 2223/6677; H01L 2224/0391; H01L 2224/05012; H01L 2224/05073; H01L 2224/05555; H01L 2224/05564; H01L 2224/05573; H01L 2224/16227; H01L 2224/16238; H01L 2225/1023; H01L 2924/182

(57) ABSTRACT

A reduced-size semiconductor die can be provided by a bumping assembly that includes one or more substrate layers, a metal layer formed over the one or more substrate layers, with the metal layer being configured for routing of a signal and having a lateral dimension, and a conductive pad formed over the metal layer and having a lateral dimension. The bumping assembly can further include an under bump metallization layer formed over the conductive pad and having a lateral dimension, such that the metal layer is electrically connected to a bump through the conductive pad and the under bump metallization layer when the bump is implemented over the under bump metallization layer, with the lateral dimension of the metal layer being less than the lateral dimension of the conductive pad.

### CROSS-REFERENCE TO RELATED APPLICATION(S)

This application claims priority to U.S. Provisional Application No. 63/464,575 filed May 7, 2023, entitled REDUCED-SIZE DIE, RELATED DEVICES AND METHODS, the disclosure of which is hereby expressly incorporated by reference herein in its entirety.

### BACKGROUND

### Field

The present disclosure relates to bumping assemblies for a semiconductor die and related devices and methods.

### DESCRIPTION OF THE RELATED ART

In many applications, a plurality of bumps are utilized to mount a semiconductor die on a substrate. Such a bumping configuration can be, for example, a flip-chip mounting configuration, and the substrate can be, for example, a packaging substrate, another die, or a circuit board.

### SUMMARY

In accordance with a number of implementations, the present disclosure relates to a bumping assembly for a semiconductor die. The bumping assembly includes one or more substrate layers, and a metal layer formed over the one or more substrate layers, with the metal layer being configured for routing of a signal and having a lateral dimension. The bumping assembly further includes a conductive pad formed over the metal layer and having a lateral dimension, and an under bump metallization layer formed over the conductive pad and having a lateral dimension, such that the metal layer is electrically connected to a bump through the conductive pad and the under bump metallization layer when the bump is implemented over the under bump metallization layer. The lateral dimension of the metal layer is less than the lateral dimension of the conductive pad.

In some embodiments, the lateral dimension of the conductive pad can be greater than or equal to the lateral dimension of the under bump metallization layer. The lateral dimension of the conductive pad can be greater than the lateral dimension of the under bump metallization layer.

In some embodiments, the lateral dimension of the metal layer being less than the lateral dimension of the conductive pad can provide a reduction in congestion of metal layers in a die associated with the bumping assembly, with the reduction in congestion of metal layers providing a reduction in size of the die. The reduction in congestion of metal layers can provide a reduction in size of the die when compared to another die without the bumping assembly.

In some embodiments, the ratio of the lateral dimension of the metal layer over the lateral dimension of the conductive pad can be less than 0.95, less than 0.90, less than 0.85, less than 0.80, less than 0.75, less than 0.70, less than 0.65, or less than 0.60.

In some embodiments, the bumping assembly can be configured to provide flip-chip mounting functionality for the semiconductor die.

In some embodiments, the conductive pad can be positioned over metal layer through a neck portion having a lateral dimension. The lateral dimension of the neck portion can be less than the lateral dimension of the metal layer. The neck portion can be formed from same material as the conductive pad.

In some embodiments, a footprint of each of the under bump metallization layer, the conductive pad and the metal layer can have a respective shape, and the footprint of the conductive pad and the footprint of the metal layer can have a similar shape. In some embodiments, the similar shape of the footprints of the conductive pad and metal layer can include, for example, a polygonal shape, such that the polygonal shape of the footprint of the metal layer is within the polygonal shape of the footprint of the conductive pad.

In some implementations, the present disclosure relates to a method for processing a semiconductor die. The method includes providing or forming one or more substrate layers, and forming a metal layer over the one or more substrate layers, with the metal layer being configured for routing of a signal and having a lateral dimension. The method further includes forming a conductive pad over the metal layer and having a lateral dimension, and forming an under bump metallization layer over the conductive pad and having a lateral dimension, such that the metal layer is electrically connected to a bump through the conductive pad and the under bump metallization layer when the bump is implemented over the under bump metallization layer. The lateral dimension of the metal layer is less than the lateral dimension of the conductive pad.

In some embodiments, the forming of the metal layer can include forming a patterned layer having an opening, and forming a metal structure within the opening, with the opening having a lateral dimension approximately the same as the lateral dimension of the metal layer. The forming of the conductive pad can include forming a first patterned passivation layer having an opening with a lateral dimension less than the lateral dimension of the metal layer, and forming a second patterned passivation layer having an opening over the first patterned passivation layer, with the opening of the second patterned passivation layer having a lateral dimension greater than the lateral dimension of the metal layer. The forming of the conductive pad can further include forming a metal structure within each of the openings of the first and second patterned passivation layers. The metal structure within the opening of the first patterned passivation layer and the metal structure within the opening of the second patterned passivation layer can be formed from same material.

In some embodiments, the forming of the under bump metallization layer can include removing the second patterned passivation layer at least about the metal structure associated with the opening of the second patterned passivation layer, and forming a passivation layer to expose a portion of an upper surface of the metal structure associated with the opening of the second patterned passivation layer. The forming of the under bump metallization layer can further include forming the under bump metallization layer over the exposed portion of the upper surface of the metal structure associated with the opening of the second patterned passivation layer to provide a bump space for receiving a bump.

According to some teachings, the present disclosure relates to a semiconductor die that includes one or more substrate layers, and an integrated circuit and/or a device implemented on one side of the one or more substrate layers and configured to provide radio-frequency functionality. The semiconductor die further includes an array of bumping assemblies implemented on the other side of the one or more substrate layers. Each bumping assembly includes a metal layer formed over the one or more substrate layers, with the metal layer being configured for routing of a signal and having a lateral dimension. The bumping assembly further includes a conductive pad formed over the metal layer and having a lateral dimension, and an under bump metallization layer formed over the conductive pad and having a lateral dimension, such that the metal layer is electrically connected to a bump through the conductive pad and the under bump metallization layer when the bump is implemented over the under bump metallization layer. The lateral dimension of the metal layer is less than the lateral dimension of the conductive pad.

In some embodiments, the semiconductor die can further include bumps secured to the under bump metallization layer of the respective bumping assembly. In some embodiments, the semiconductor die can be implemented as a flip-chip die.

In some embodiments, the lateral dimension of the metal layer being less than the lateral dimension of the conductive pad can provide a reduction in congestion of metal layers associated with the bumping assemblies, with the reduction in congestion of metal layers providing a reduction in size of the semiconductor die when compared to another semiconductor die without the bumping assemblies.

In some implementations, the present disclosure relates to a packaged module that includes a packaging substrate and a semiconductor die mounted on the packaging substrate. The semiconductor die includes one or more substrate layers, an integrated circuit and/or a device implemented on one side of the one or more substrate layers and configured to provide radio-frequency functionality. The semiconductor die further includes an array of bumping assemblies implemented on the other side of the one or more substrate layers. Each bumping assembly includes a metal layer formed over the one or more substrate layers, with the metal layer being configured for routing of a signal and having a lateral dimension. The bumping assembly further includes a conductive pad formed over the metal layer and having a lateral dimension, and an under bump metallization layer formed over the conductive pad and having a lateral dimension, such that the metal layer is electrically connected to a bump through the conductive pad and the under bump metallization layer when the bump is implemented over the under bump metallization layer. The lateral dimension of the metal layer is less than the lateral dimension of the conductive pad.

In some embodiments, the packaging substrate can include a first side and a second side, with the second side being configured to allow mounting of the packaged module onto a circuit board. In some embodiments, the semiconductor die can be mounted on the first or second side of the packaging substrate.

In some embodiments, the packaged module can further include another semiconductor die mounted on the first or second side of the packaging substrate.

In some embodiments, the semiconductor die can be mounted on one of the first and second sides of the packaging substrate, and the other semiconductor die can be mounted on the other side of the packaging substrate, such that the packaged module is a dual-sided module.

In some embodiments, the packaged module can further include a mold structure implemented on at least the first side of the packaging substrate. In some embodiments, the packaged module can further include a conformal shielding layer implemented to cover the mold structure and side surfaces of the packaged module.

In accordance with some implementations, the present disclosure relates to a wireless device that includes a transceiver, an antenna, and a radio-frequency device implemented to be electrically between the transceiver and the antenna. The radio-frequency device includes a semiconductor die that includes one or more substrate layers, and an integrated circuit and/or a device implemented on one side of the one or more substrate layers and configured to provide radio-frequency functionality. The semiconductor die further includes an array of bumping assemblies implemented on the other side of the one or more substrate layers. Each bumping assembly includes a metal layer formed over the one or more substrate layers, with the metal layer being configured for routing of a signal and having a lateral dimension. The bumping assembly further includes a conductive pad formed over the metal layer and having a lateral dimension, and an under bump metallization layer formed over the conductive pad and having a lateral dimension, such that the metal layer is electrically connected to a bump through the conductive pad and the under bump metallization layer when the bump is implemented over the under bump metallization layer. The lateral dimension of the metal layer is less than the lateral dimension of the conductive pad.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A shows a cross-sectional side view of a conventional bumping configuration, with a bump present.

FIG. 1B shows a plan view of the bumping configuration of FIG. 1A, without a bump.

FIG. 2A shows a cross-sectional side view of a bumping configuration, with a bump present.

FIG. 2B shows a plan view of the bumping configuration of FIG. 2A, without a bump.

FIG. 3A shows a cross-sectional side view of an example bumping configuration having one or more features as described herein, with a bump present.

FIG. 3B shows a plan view of the bumping configuration of FIG. 3A, without a bump.

FIG. 4 shows various lateral dimensions of footprints associated with the three example bumping configurations of FIGS. 1 to 3.

FIGS. 5A to 5C show that bumping configurations having one or more features as described herein can be implemented with different footprint shapes.

FIGS. 6A to 6I show various stages of a process that can be implemented to form a bumping configuration having one or more features as described herein.

FIG. 7 shows an example of a packaged die having a substrate and a plurality of bumps, where some or all of the bumps can be attached to the substrate by a bumping configuration as described herein.

FIG. 8 shows an example of a packaged module where one or more die having a bumping configuration as described herein can be mounted to either or both sides of a packaging substrate.

FIG. 9 depicts an example wireless device having one or more die as described herein.

### DETAILED DESCRIPTION OF SOME EMBODIMENTS

The headings provided herein, if any, are for convenience only and do not necessarily affect the scope or meaning of the claimed invention.

Described herein are various examples related to a die, such as a semiconductor die, having reduced size by utilizing smaller pads at lower level metal(s) under bumps. In such a configuration, the top metal layer can maintain its lateral size, thereby providing bump related reliability that allows, for example, standard bumping stack up configurations.

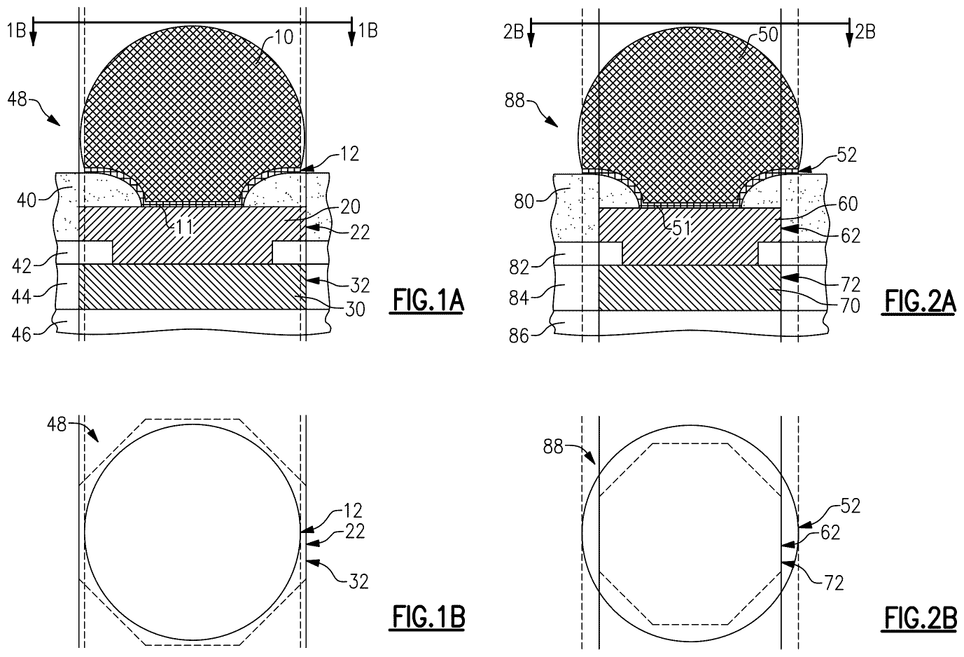

FIG. 1A shows a cross-sectional side view of a conventional bumping configuration 48 with a bump 10 present, and FIG. 1B shows a plan view of the same bumping configuration 48 without a bump. A number of such bumping configurations can be utilized for a die to allow mounting of the die (e.g., flip-chip mounting) on a substrate such as a packaging substrate, another die, circuit board, etc.

Although some of the examples are described herein in the context of ball shaped bumps, it will be understood that one or more features of the present disclosure can also be utilized for pillar bumps such as copper pillars (CuP).

Referring to FIGS. 1A and 1B, the conventional bumping configuration 48 includes an under bump metallization (UBM) layer 11 formed over a passivation layer 40 and an exposed surface of a conductive pad 20, where the exposed surface is generally defined by an opening in the passivation layer 40. As is generally understood, the UBM layer 11 provides a desirable interface between a bump (e.g., 10 in FIG. 1A) and the conductive pad 20.

Referring to FIGS. 1A and 1B, the conductive pad 20 is shown to be formed over a lower level metal layer 30 through a patterned opening of a passivation layer 42 that may or may not be formed from same material as the passivation layer 40. The metal layer 30 is shown to be part of a layer that includes a patterned layer 44 that may or may not be formed from same material as the layer 42. The layer having the metal layer 30 and the patterned layer 44 is shown to be formed over one or more substrate layers collectively indicated as 46.

Accordingly, an electrical connection is shown to be provided between the metal layer 30 and the bump 10 through the conductive pad 20 and the UBM 11 when the bump 10 is formed over the UBM 11.

In the example of FIGS. 1A and 1B, the UBM 11 is shown to have a circular shape footprint 12, the conductive pad 20 is shown to have an octagonal shaped footprint 22, and the metal layer 30 is shown to have an octagonal shaped footprint 32 when viewed in the plan view of FIG. 1B. For such example footprint shapes of the UBM 11, conductive pad 20 and metal layer 30 of the bumping configuration 48 of FIGS. 1A and 1B, representative lateral dimensions are indicated on the left footprint depiction in FIG. 4.

FIG. 2A shows a cross-sectional side view of a bumping configuration 88 with a bump 50 present, and FIG. 2B shows a plan view of the same bumping configuration 88 without a bump. Such a configuration includes reduced lateral dimensions for both of conductive pad and lower level metal layer, but with a UBM having a lateral dimension that is similar to the UBM of the conventional bumping configuration 48 of FIGS. 1A and 1B.

More particularly, and referring to FIGS. 2A and 2B, the bumping configuration 88 includes an under bump metallization (UBM) layer 51 formed over a passivation layer 80 and an exposed surface of a conductive pad 60, where the exposed surface is generally defined by an opening in the passivation layer 80. Thus, the UBM layer 51 provides a desirable interface between a bump (e.g., 50 in FIG. 2A) and the conductive pad 60.

Referring to FIGS. 2A and 2B, the conductive pad 60 is shown to be formed over a lower level metal layer 70 through a patterned opening of a passivation layer 82 that may or may not be formed from same material as the passivation layer 80. The metal layer 70 is shown to be part of a layer that includes a patterned layer 84 that may or may not be formed from same material as the layer 82. The layer having the metal layer 70 and the patterned layer 84 is shown to be formed over one or more substrate layers collectively indicated as 86.

Accordingly, an electrical connection is shown to be provided between the metal layer 70 and the bump 50 through the conductive pad 60 and the UBM 51 when the bump 50 is formed over the UBM 51.

In the example of FIGS. 2A and 2B, the UBM 51 is shown to have a circular shape footprint 52, the conductive pad 60 is shown to have an octagonal shaped footprint 62, and the metal layer 70 is shown to have an octagonal shaped footprint 72 when viewed in the plan view of FIG. 2B. For such example footprint shapes of the UBM 51, conductive pad 60 and metal layer 70 of the bumping configuration 88 of FIGS. 2A and 2B, representative lateral dimensions are indicated on the right footprint depiction in FIG. 4.

Referring to the example of FIGS. 2A and 2B, and assuming that the lateral dimension of the UBM footprint 52 is approximately the same as the lateral dimension of the UBM footprint 12 of FIGS. 1A and 1B, it is noted that each of lateral dimensions of the conductive pad footprint 62 and the metal layer footprint 72 is less than the lateral dimension of the UBM footprint 52.

It is further noted that such a configuration can result in packaging reliability and/or efficiency issue(s). For example, the reduced lateral dimension of the conductive pad footprint 62 relative to the UBM footprint 52 may result in an increased difficulty in reliable formation of UBMs on the respective contact pads. Further, an increased (e.g., double) passivation may be required to accommodate the reduced lateral dimensions of the conductive pad footprint 62 and the metal layer footprint 72, thereby increasing the cost of a corresponding die.

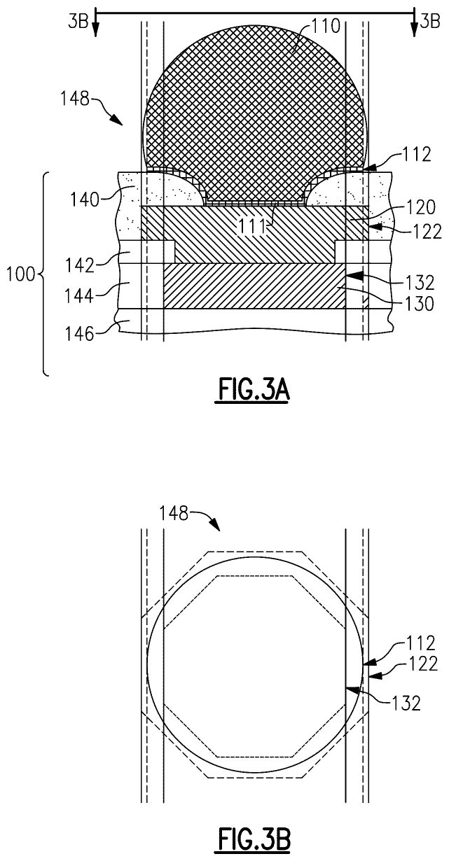

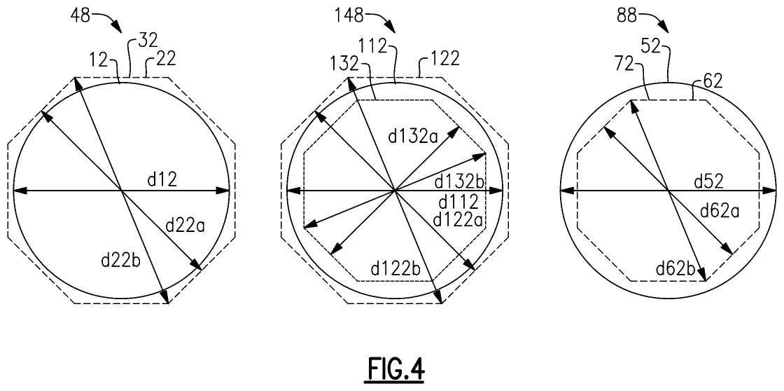

FIG. 3A shows a cross-sectional side view of a bumping configuration 148 with a bump 110 present, and FIG. 3B shows a plan view of the same bumping configuration 148 without a bump. Such a configuration includes a reduced lateral dimension for a lower level metal layer, but with UBM and conductive pad having lateral dimensions that are similar to the UBM and conductive pad of the conventional bumping configuration 48 of FIGS. 1A and 1B.

More particularly, and referring to FIGS. 3A and 3B, the bumping configuration 148 includes an under bump metallization (UBM) layer 111 formed over a passivation layer 140 and an exposed surface of a conductive pad 120, where the exposed surface is generally defined by an opening in the passivation layer 140. Thus, the UBM layer 111 provides a desirable interface between a bump (e.g., 110 in FIG. 3A) and the conductive pad 120.

Referring to FIGS. 3A and 3B, the conductive pad 120 is shown to be formed over a lower level metal layer 130 through a patterned opening of a passivation layer 142 that may or may not be formed from same material as the passivation layer 140. The metal layer 130 is shown to be part of a layer that includes a patterned layer 144 that may or may not be formed from same material as the layer 142. The layer having the metal layer 130 and the patterned layer 144 is shown to be formed over one or more substrate layers collectively indicated as 146.

Accordingly, an electrical connection is shown to be provided between the metal layer 130 and the bump 110 through the conductive pad 120 and the UBM 111 when the bump 110 is formed over the UBM 111.

In the example of FIGS. 3A and 3B, the UBM 111 is shown to have a circular shape footprint 112, the conductive pad 120 is shown to have an octagonal shaped footprint 122, and the metal layer 130 is shown to have an octagonal shaped footprint 132 when viewed in the plan view of FIG. 3B. For such example footprint shapes of the UBM 111, conductive pad 120 and metal layer 130 of the bumping configuration 148 of FIGS. 3A and 3B, representative lateral dimensions are indicated on the middle footprint depiction in FIG. 4.

Referring to the example of FIGS. 3A and 3B, it is noted that use of reduced lateral dimension of lower level metal layers such as the metal layer 130 can provide a number of desirable features. For example, congestion of metal layers can be reduced, thereby reducing white space at a corresponding level of a bumping configuration. Accordingly, a reduction in die size can also be provided.

It is further noted that use of a conductive pad 120 having a non-reduced lateral dimension (relative to the UBM's lateral dimension) results in bump related reliability being unaffected when compared to the example of FIGS. 1A and 1B.

As described above, FIG. 4 shows various lateral dimensions of footprints associated with the three example bumping configurations of FIGS. 1 to 3. More particularly, the left side of FIG. 4 shows lateral dimensions of the footprints 12 (of the UBM layer 11), 22 (of the conductive pad 20) and 32 (of the metal layer 30) of the bumping configuration 48 of FIGS. 1A and 1B. The dimension indicated as d12 is the diameter of the footprint 12 of the UBM layer 11; the dimension indicated as d22a is the distance between two opposing sides of the octagonal shape of the footprint 22 of the conductive pad 20, as well as the footprint 32 of the metal layer 30; and the dimension indicated as d22b is the distance between two opposing vertices of the octagonal shape of the footprint 22 of the conductive pad 20, as well as the footprint 32 of the metal layer 30.

The right side of FIG. 4 shows lateral dimensions of the footprints 52 (of the UBM layer 51), 62 (of the conductive pad 60) and 72 (of the metal layer 70) of the bumping configuration 88 of FIGS. 2A and 2B. The dimension indicated as d52 is the diameter of the footprint 52 of the UBM layer 51; the dimension indicated as d62a is the distance between two opposing sides of the octagonal shape of the footprint 62 of the conductive pad 60, as well as the footprint 72 of the metal layer 70; and the dimension indicated as d62b is the distance between two opposing vertices of the octagonal shape of the footprint 62 of the conductive pad 60, as well as the footprint 72 of the metal layer 70.

The middle portion of FIG. 4 shows lateral dimensions of the footprints 112 (of the UBM layer 111), 122 (of the conductive pad 120) and 132 (of the metal layer 130) of the bumping configuration 148 of FIGS. 3A and 3B. The dimension indicated as d112 is the diameter of the footprint 112 of the UBM layer 111. The dimension indicated as d122a is the distance between two opposing sides of the octagonal shape of the footprint 122 of the conductive pad 120; and the dimension indicated as d132a is the distance between two opposing sides of the octagonal shape of the footprint 132 of the metal layer 130. The dimension indicated as d122b is the distance between two opposing vertices of the octagonal shape of the footprint 122 of the conductive pad 120; and the dimension indicated as dl 32b is the distance between two opposing vertices of the octagonal shape of the footprint 132 of the metal layer 130.

As examples, for the bumping configuration 48 of FIGS. 1A and 1B, the dimension d12 for the UBM layer can be approximately 70 μm, and the dimension d22a for the conductive pad and the metal layer can be approximately 80 μm. For the bumping configuration 88 of FIGS. 2A and 2B, the dimension d52 for the UBM layer can be approximately 70 μm, and the dimension d62a for the conductive pad and the metal layer can be approximately 55 μm. For the bumping configuration 148 of FIGS. 3A and 3B, the dimension d112 for the UBM layer can be approximately 70 μm, the dimension d122a for the conductive pad can be approximately 80 μm, and the dimension d132a for the metal layer can be approximately 55 μm. In the example of FIGS. 3A and 3B, the neck portion of the conductive pad 120 can have a lateral dimension of approximately 51 μm.

Referring to the examples of FIGS. 1 to 4, it is noted that in some embodiments, a bumping configuration having one or more features as described herein can include a UBM layer having a lateral dimension d_{UBM}, a conductive pad underneath the UBM layer and having a lateral dimension d_{pad}, and a metal layer underneath the conductive pad and having a lateral dimension d_{M}, where d_{UBM} is less than or equal to d_{pad}, and d_{M} is less than d_{pad}. In some embodiments, d_{M} can be less than d_{pad} such that d_{M}/d_{pad} is less than 0.95, less than 0.90, less than 0.85, less than 0.80, less than 0.75, less than 0.70, less than 0.65, or less than 0.60.

In the examples of FIGS. 1 to 4, footprints of the respective conductive pads (20 in FIG. 1A, 60 in FIG. 2A, 120 in FIG. 3A) and metal layers (30 in FIG. 1A, 70 in FIG. 2A, 130 in FIG. 3A) are depicted as having an octagonal shape, and footprints of the respective UBM layers (11 in FIG. 1A, 51 in FIG. 2A, 111 in FIG. 3A) are depicted as having a circular shape. It will be understood that such shapes are examples, and other shapes can also be utilized to implement one or more features as described herein.

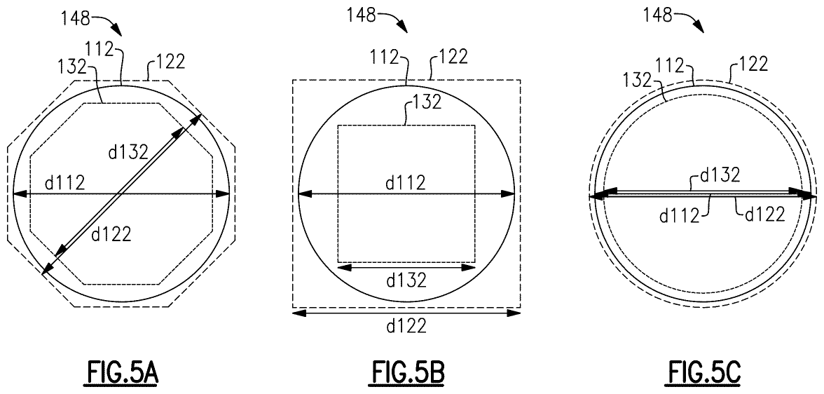

FIGS. 5A to 5C show non-limiting examples where conductive pads and metal layers as described herein can have different shapes. For example, FIG. 5A shows a bumping configuration 148 that is similar to the bumping configuration 148 of FIG. 3B, where a conductive pad (120 in FIG. 3A) has an octagonal shaped footprint 122, and a metal layer (130 in FIG. 3A) also has an octagonal shaped footprint 132. For such footprints, an example dimension between two opposing sides of the octagonal footprint 122 is indicated as d122, and an equivalent dimension between two opposing sides of the octagonal footprint 132 is indicated as d132.

In another example, FIG. 5B shows a bumping configuration 148 where a conductive pad (120 in FIG. 3A) has rectangular (e.g., square) shaped footprint 122, and a metal layer (130 in FIG. 3A) also has rectangular (e.g., square) shaped footprint 132. For such footprints, an example dimension between two opposing sides of the square footprint 122 is indicated as d122, and an equivalent dimension between two opposing sides of the square footprint 132 is indicated as d132.

In another example, FIG. 5C shows a bumping configuration 148 where a conductive pad (120 in FIG. 3A) has circular shaped footprint 122, and a metal layer (130 in FIG. 3A) also has circular shaped footprint 132. For such footprints, an example dimension of the diameter of the circular footprint 122 is indicated as d122, and an equivalent dimension of the diameter of the circular footprint 132 is indicated as d132.

In each of the examples of FIGS. 5A to 5C, the footprint 122 of the respective conductive pad and the footprint 132 of the respective metal layer are shown to be oriented the same such that the smaller footprint (132) is nested within the larger footprint (122) with symmetry. It will be understood that in some embodiments, one footprint may or may not have symmetry with respect to the other footprint.

For example, in each of the footprint configurations of FIGS. 5A and 5B, the smaller footprint (132) may be rotated with respect to the larger footprint (122) (when viewed as shown), such that the two footprints are asymmetric with respect to each other. In some embodiments, in such an asymmetric arrangement of the two footprints of the conductive pad and metal layer, the equivalent dimensions d122 and d132 can be selected such that d132 is less than d122.

In each of the examples of FIGS. 5A to 5C, the footprint 112 of the respective UBM layer (111 in FIG. 3A) is depicted as having a circular shape. It will be understood that such a circular shape is an example, and other footprint shapes can also be utilized for a UBM layer to implement one or more features as described herein.

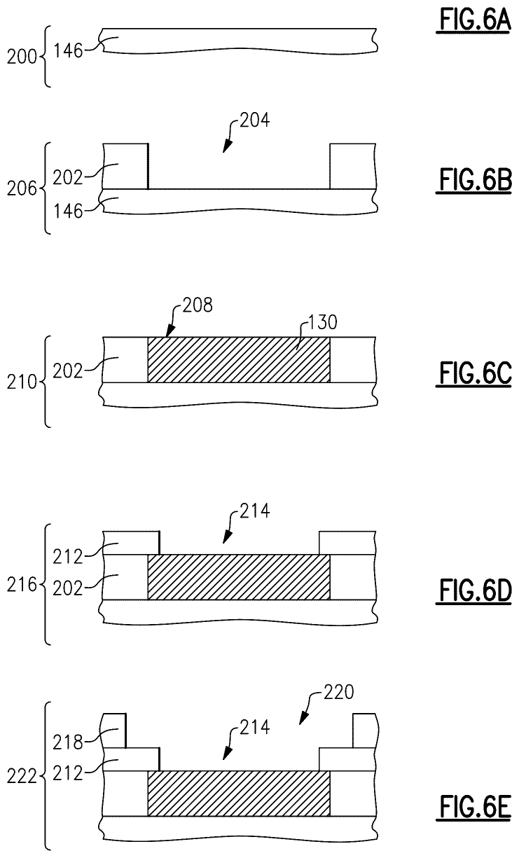

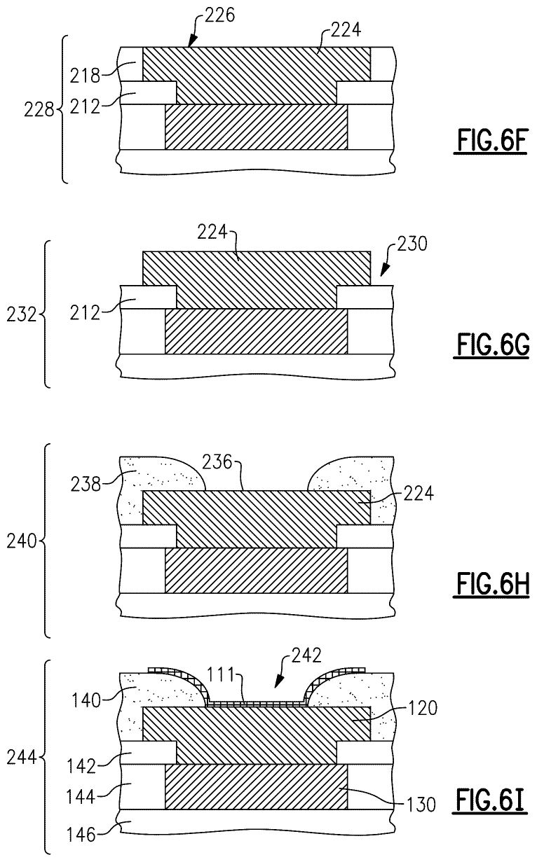

FIGS. 6A to 6I show various stages of a process of formation of a bumping configuration having one or more features as described herein.

FIG. 6A shows an assembly 200 that includes one or more substrate layers, collectively indicated as 146.

FIG. 6B shows a stage where a patterned layer 202 having an opening can be provided over the substrate layer(s) 146 so as to form an assembly 206.

FIG. 6C shows a stage where a metal layer 130 having a lateral dimension is formed within the opening (204 in FIG. 6B) of the patterned layer 202 so as to form an assembly 210. The metal layer 130 is shown to include an upper surface 208.

FIG. 6D shows a stage where a first patterned passivation layer 212 is formed over the patterned layer 202 and the metal layer 130 to provide an opening 214 having a lateral dimension less than the lateral dimension of the metal layer 130, so as to form an assembly 216.

FIG. 6E shows a stage where a second patterned passivation layer 218 is formed over the first passivation layer 212 to provide an opening 220 having a lateral dimension greater than the lateral dimension of the metal layer 130, so as to form an assembly 222.

FIG. 6F shows a stage where a metal structure 224 is formed to fill the opening (214 in FIG. 6E) of the first passivation layer 212 and the opening 220 of the second passivation layer 218 and provide an upper surface 226, so as to form an assembly 228.

FIG. 6G shows a stage where the second passivation layer 218 can be removed to provide a space 230 about the larger lateral dimension portion of the metal structure 224, so as to form an assembly 232.

FIG. 6H shows a stage where a passivation layer 238 can be formed over the metal structure 224 and provide an exposed portion 236 of the upper surface (226 in FIG. 6F) of the metal structure 224, so as to form an assembly 240.

FIG. 6I shows a stage where a UBM layer 111 can be formed over the metal structure (224 in FIG. 6H) and the passivation layer (238 in FIG. 6H) to provide a bump space 242 for receiving a bump, so as to form an assembly 244 that is similar to the bump configuration 148 of FIGS. 3A and 3B. Accordingly, in FIG. 6I, the metal structure 224 of FIGS. 6F to 6H is indicated as 120.

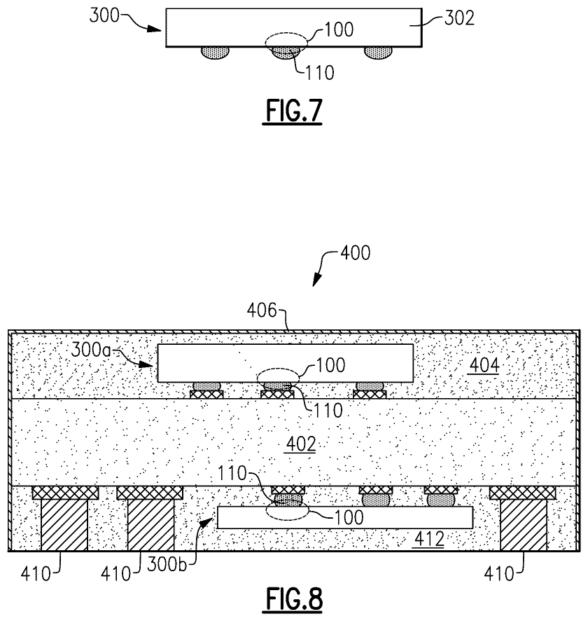

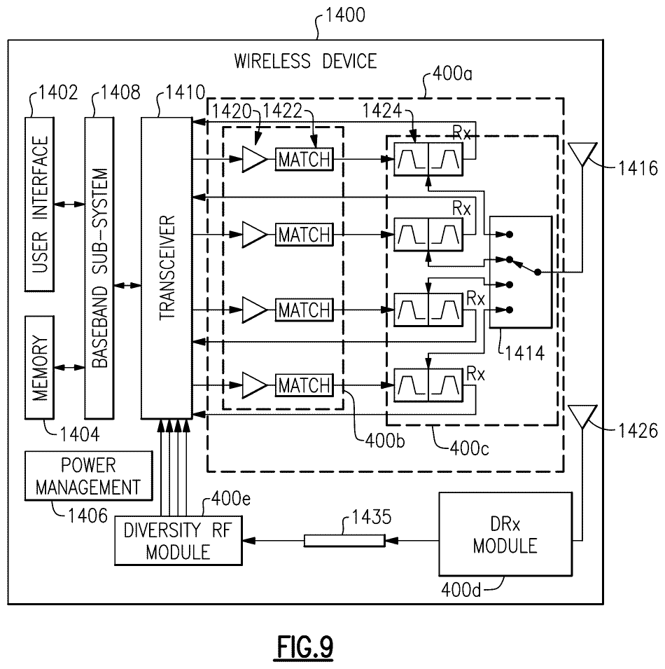

FIG. 7 shows an example of a die 300 having a substrate 302 and an integrated circuit thereon. Such a die is shown to be provided with a plurality of bumps 110, and each of such bumps can be attached to a bumping configuration 100. In some embodiments, the bumping configuration 100 can include some or all of the features described herein in reference to FIGS. 3A, 3B, 4, 5A to 5C and 6A to 6I. In some embodiments, the die 300 of FIG. 7 can be implemented as a flip-chip die.

FIG. 8 shows an example of a packaged module 400 having first and second die 300a, 300b mounted to first and second sides of a packaging substrate 402, respectively. In the example of FIG. 8, each of the first and second die 300a, 300b is shown to be similar to the example die 300 of FIG. 7 in the context of the bumping configuration 100.

In the example of FIG. 8, the first side of the packaging substrate 402 is shown to be provided with a first mold structure 404, and the second side of the packaging substrate 402 is shown to be provided with a second mold structure 412. The second side of the packaging substrate 402 is also shown to be provided with a plurality of conductive mounting features 410 such as metal posts.

In the example of FIG. 8, the packaged module 400 is shown to also include a conformal shielding layer 406 that covers the upper surface and side walls of the module. Such a shielding layer can provide electromagnetic shielding between a location within the module 400 and a location outside of the module 400.

In some implementations, a device and/or a circuit having one or more features described herein can be included in an RF electronic device such as a wireless device. In some embodiments, such a wireless device can include, for example, a cellular phone, a smart-phone, a hand-held wireless device with or without phone functionality, a wireless tablet, etc.

FIG. 9 depicts an example wireless device 1400 having one or more advantageous features described herein. In the example of FIG. 9, an RF module having one or more features as described herein can be implemented in a number of places. For example, an RF module may be implemented as a front-end module (FEM) indicated as 400a. In another example, an RF module may be implemented as a power amplifier module (PAM) indicated as 400b. In another example, an RF module may be implemented as an antenna switch module (ASM) indicated as 400c. In another example, an RF module may be implemented as a diversity receive (DRx) module indicated as 400d. It will be understood that an RF module having one or more features as described herein can be implemented with other combinations of components.

Referring to FIG. 9, power amplifiers (PAs) 1420 can receive their respective RF signals from a transceiver 1410 that can be configured and operated to generate RF signals to be amplified and transmitted, and to process received signals. The transceiver 1410 is shown to interact with a baseband sub-system 1408 that is configured to provide conversion between data and/or voice signals suitable for a user and RF signals suitable for the transceiver 1410. The transceiver 1410 can also be in communication with a power management component 1406 that is configured to manage power for the operation of the wireless device 1400.

The baseband sub-system 1408 is shown to be connected to a user interface 1402 to facilitate various input and output of voice and/or data provided to and received from the user. The baseband sub-system 1408 can also be connected to a memory 1404 that is configured to store data and/or instructions to facilitate the operation of the wireless device, and/or to provide storage of information for the user.

In the example wireless device 1400, outputs of the PAs 1420 are shown to be matched (via respective match circuits 1422) and routed to their respective duplexers 1424. Such amplified and filtered signals can be routed to a primary antenna 1416 through an antenna switch 1414 for transmission. In some embodiments, the duplexers 1424 can allow transmit and receive operations to be performed simultaneously using a common antenna (e.g., primary antenna 1416). In FIG. 9, received signals are shown to be routed to “Rx” paths that can include, for example, a low-noise amplifier (LNA).

In the example of FIG. 9, the wireless device 1400 also includes the diversity antenna 1426 and the shielded DRx module 400d that receives signals from the diversity antenna 1426. The shielded DRx module 400d processes the received signals and transmits the processed signals via a transmission line 1435 to a diversity RF module 400e that further processes the signal before feeding the signal to the transceiver 1410.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A bumping assembly for a semiconductor die, comprising:
one or more substrate layers;
a metal layer formed over the one or more substrate layers, the metal layer configured for routing of a signal and having a lateral dimension;
a conductive pad formed over the metal layer and having a lateral dimension; and
an under bump metallization layer formed over the conductive pad and having a lateral dimension, such that the metal layer is electrically connected to a bump through the conductive pad and the under bump metallization layer when the bump is implemented over the under bump metallization layer, the lateral dimension of the metal layer less than the lateral dimension of the conductive pad.

2. The bumping assembly of claim 1 wherein the lateral dimension of the conductive pad is greater than or equal to the lateral dimension of the under bump metallization layer.

3. The bumping assembly of claim 2 wherein the lateral dimension of the conductive pad is greater than the lateral dimension of the under bump metallization layer.

4. The bumping assembly of claim 1 wherein the lateral dimension of the metal layer being less than the lateral dimension of the conductive pad provides a reduction in congestion of metal layers in a die associated with the bumping assembly, the reduction in congestion of metal layers providing a reduction in size of the die.

5. The bumping assembly of claim 4 wherein the reduction in congestion of metal layers provide a reduction in size of the die when compared to another die without the bumping assembly.

6. The bumping assembly of claim 1 wherein the ratio of the lateral dimension of the metal layer over the lateral dimension of the conductive pad is less than 0.95, less than 0.90, less than 0.85, less than 0.80, less than 0.75, less than 0.70, less than 0.65, or less than 0.60.

7. The bumping assembly of claim 1 wherein the bumping assembly is configured to provide flip-chip mounting functionality for the semiconductor die.

8. The bumping assembly of claim 1 wherein the conductive pad is positioned over metal layer through a neck portion having a lateral dimension.

9. The bumping assembly of claim 8 wherein the lateral dimension of the neck portion is less than the lateral dimension of the metal layer.

10. The bumping assembly of claim 8 wherein the neck portion is formed from same material as the conductive pad.

11. The bumping assembly of claim 1 wherein a footprint of each of the under bump metallization layer, the conductive pad and the metal layer has a respective shape, the footprint of the conductive pad and the footprint of the metal layer having a similar shape.

12. The bumping assembly of claim 11 wherein the similar shape of the footprints of the conductive pad and metal layer includes a polygonal shape, such that the polygonal shape of the footprint of the metal layer is within the polygonal shape of the footprint of the conductive pad.

13. A method for processing a semiconductor die, the method comprising:
providing or forming one or more substrate layers;
forming a metal layer over the one or more substrate layers, the metal layer configured for routing of a signal and having a lateral dimension;
forming a conductive pad over the metal layer and having a lateral dimension; and
forming an under bump metallization layer over the conductive pad and having a lateral dimension, such that the metal layer is electrically connected to a bump through the conductive pad and the under bump metallization layer when the bump is implemented over the under bump metallization layer, the lateral dimension of the metal layer less than the lateral dimension of the conductive pad.

14. The method claim 13 wherein the forming of the metal layer includes forming a patterned layer having an opening, and forming a metal structure within the opening, the opening having a lateral dimension approximately the same as the lateral dimension of the metal layer.

15. The method claim 14 wherein the forming of the conductive pad includes forming a first patterned passivation layer having an opening with a lateral dimension less than the lateral dimension of the metal layer, and forming a second patterned passivation layer having an opening over the first patterned passivation layer, the opening of the second patterned passivation layer having a lateral dimension greater than the lateral dimension of the metal layer.

16. The method claim 15 wherein the forming of the conductive pad further includes forming a metal structure within each of the openings of the first and second patterned passivation layers.

17. The method claim 16 wherein the metal structure within the opening of the first patterned passivation layer and the metal structure within the opening of the second patterned passivation layer are formed from same material.

18. The method claim 16 wherein the forming of the under bump metallization layer includes removing the second patterned passivation layer at least about the metal structure associated with the opening of the second patterned passivation layer, and forming a passivation layer to expose a portion of an upper surface of the metal structure associated with the opening of the second patterned passivation layer.

19. The method claim 18 wherein the forming of the under bump metallization layer further includes forming the under bump metallization layer over the exposed portion of the upper surface of the metal structure associated with the opening of the second patterned passivation layer to provide a bump space for receiving a bump.

20. A semiconductor die comprising:
one or more substrate layers;
an integrated circuit and/or a device implemented on one side of the one or more substrate layers and configured to provide radio-frequency functionality; and
an array of bumping assemblies implemented on the other side of the one or more substrate layers, each bumping assembly including a metal layer formed over the one or more substrate layers, the metal layer configured for routing of a signal and having a lateral dimension, the bumping assembly further including a conductive pad formed over the metal layer and having a lateral dimension, and an under bump metallization layer formed over the conductive pad and having a lateral dimension, such that the metal layer is electrically connected to a bump through the conductive pad and the under bump metallization layer when the bump is implemented over the under bump metallization layer, the lateral dimension of the metal layer less than the lateral dimension of the conductive pad.

21. (canceled)

22. (canceled)

23. (canceled)

24. (canceled)

25. (canceled)

26. (canceled)

27. (canceled)

28. (canceled)

29. (canceled)

30. (canceled)

31. (canceled)
